(19) United States
(12) Patent Application Publication
(10) Pub. No.: US 2026/0242649 A1
(43) Pub. Date: Aug. 20, 2026

(54) ELECTRONIC EQUIPMENT COOLING SYSTEM WITH HEAT TRANSFER FLUID

(71) Applicant: ENOVER ISI SISTEMLERI ANONIM SIRKETI, Ankara (TR)

(72) Inventor: Malik ÇAGLAR, Ankara (TR)

(21) Appl. No.: 19/480,382

(22) PCT Filed: Aug. 28, 2023
(86) PCT No.: PCT/TR2023/050871

§ 371 Date: Oct. 31, 2025

(30) Foreign Application Priority Data
Mar. 10, 2023 (TR) 2023/002718

(51) Int. Cl. C09K 5/04; H05K 7/20

(52) U.S. Cl. CPC C09K 5/04; H05K 7/20318

(57) ABSTRACT

The invention relates to the electronic equipment cooling system (1) with heat transfer fluid, which quickly removes the unwanted heat from the heated parts of the electronic equipment by transferring it to the phase changeable heat transfer fluid in order to cool the electronic card and all electronic equipment. The invention especially relates to the electronic equipment cooling system, which receives the heat energy from the heated component of the electronic equipment with the help of the plate and transmits this heat energy to the fins, condensing here with the help of the fans, allowing the electronic board to cool, and containing a phase changeable heat transfer fluid containing 10-200 nanometers colemanite, borax, Al₂O₃, SiO₃, CuO, TiO₂, SiL, boron carbide, szaybelite, boron solid particles.

### TECHNICAL FIELD

The invention relates to the electronic equipment cooling system with heat transfer fluid, which quickly removes the unwanted heat from the heated parts of the electronic equipment by transferring it to the heat transfer fluid, which can change phase, in order to cool the electronic equipment.

The invention especially relates to the electronic equipment cooling system, which receives the heat energy from the heated component of the electronic equipment with the help of the plate and transmits this heat energy to the fins, condensing here with the help of the fans, allowing the electronic board to cool, and containing a phase changeable heat transfer fluid containing 10-200 nanometers colemanite, borax, Al₂O₃, SiO₃, CuO, TiO₂, SiL, boron carbide, szaybelite, boron solid particles.

### THE KNOWN STATE OF THE TECHNIQUE

The use of electronic elements has become widespread in all areas of modern life. Electronic devices are used in workplaces, homes, automobiles and many similar areas. The reason for these devices being used to fail or slow down very much is usually the overheating of the small parts that make up the system.

Electronic elements work by passing an electric current through them and thus become a potential heat generator. With the continuation of current flow, heat production also continues if the heat cannot be discharged into the heat well through a passageway, the temperature will gradually increase. If the heat transfer path is weak here, the electronic element will be destroyed and the current will stop.

Air cooling is the most widely used cooling method. The main reason for this is that the air is present in the atmosphere in the desired amount. Closed cavities are equipped with air vents so that cool air can enter the electronic elements inside the closed cavities and the heated air can escape freely.

The reduction in the dimensions of the electronic elements revealed more heat production per unit area. As the power of the system increases, the heat flux per unit area will increase. For systems that are getting smaller in size, cooling technologies are being developed with synthetic liquids instead of air, which is now widely used. In the cooling of electronic equipment with liquid, the liquid is in a closed system. The pipes in which the refrigerant is located are placed around the electronic equipment. The refrigerant circulating in the system takes the high heat in the electronic equipment and carries it out of the system.

There are negative aspects such as high costs of cooling systems used in the current technique, inability of refrigerants used in cooling systems to cool the system adequately, inability to be applied to small areas, and leaks that occur especially in systems that use liquids for cooling.

The phase change fluids used in the present technique have a heat transfer coefficient of 1100 W/mK. Therefore, they do not respond quickly to heating.

As a result, the need for a new economical, convenient, electronic equipment cooling system with heat transfer fluid and the inadequacy of the existing solutions have made it necessary to make a development in the relevant technical field in order to solve the above-mentioned problems existing in the current technique.

### THE PURPOSE OF THE INVENTION

The invention relates to a cooling system that quickly removes unwanted heat from the getting warm parts of electronic equipment by transferring it to a phase changeable heat transfer fluid, with the aim of cooling the electronic card and all electronic equipment, which was developed to eliminate the disadvantages mentioned above and to bring new advantages to the related technical field.

The most important aim of the invention is to contain a heat transfer pipe with a phase changeable heat transfer fluid. The phase-change fluid conducts heat by passing from the liquid phase to the vapor phase. After transmitting the heat, it condenses and returns. Thanks to the solid particles between 10-200 nanometers such as colemanite, borax, Al₂O₃, SiO₃, CuO, TiO₂, SiL, szaibelyite, boron carbide, boron in the phase change heat transfer system, evaporation accelerates with the heat taken Since these nanoparticles act as a catalyst, heat transfer is done quickly. After heat transfer, these solid particles do not clump together and do not stick to each other during condensation. During condensation, it cools slowly thanks to the nano-sized solid particles that crash into the inner walls of the heat pipe. In this way, it has a high capacity to retain heat. Thanks to these nanoparticles, heat pipes can be prepared without vacuuming.

Another aim of the invention is that the heat transfer fluid contained in it does not have any flammable, explosive, allergen, carcinogenic, pathogenic effects, so it does not adversely affect the environment and human health.

Another aim of the invention is that the fluid that can change phase as a result of our R&D studies has a heat transfer coefficient of 16098 W/mK. Therefore, the invention provides a fast heat transfer by reacting very quickly.

Another aim of the invention is that the heat transfer fluid in it turns into gas when it reaches atmospheric conditions, and if there is a leak in the system, there is no problem due to liquid contact.

The structural and characteristic features of the invention and all its advantages will be understood more clearly thanks to the figures given below and the detailed description written with reference to these figures and for this reason, the evaluation should be made taking into account these figures and detailed explanation.

### FIGURES TO HELP UNDERSTAND THE INVENTION

FIG. 1—The drawing that gives the general view of the subject of the invention is an electronic equipment cooling system with heat pipe and fan heat transfer fluid with phase changeable heat transfer fluid.

FIG. 2—The drawing that gives the view of the front side of the subject of the invention is an electronic equipment cooling system with heat pipe and fan heat transfer fluid with phase changeable heat transfer fluid.

FIG. 3—The drawing that gives the view of the back side of the subject of the invention is an electronic equipment cooling system with heat pipe and fan heat transfer fluid with phase changeable heat transfer fluid.

### REFERENCE NUMBERS

1—Electronic equipment cooling system with heat transfer fluid
2—Electronic equipment
3—Heating component of electronic equipment
4—Sheet
5—Heat transfer pipes
6—Fins
7—Fans

### DETAILED DESCRIPTION OF THE INVENTION

In this detailed description, preferred embodiments of the electronic equipment cooling system (1) with heat transfer fluid are explained for the sake of better understanding only and without any limiting effect.

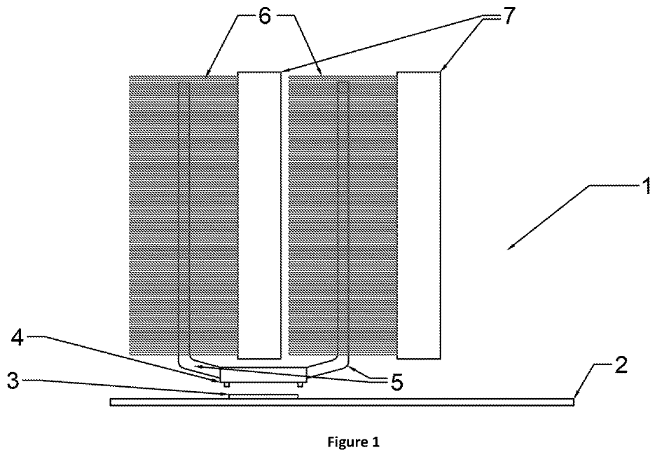

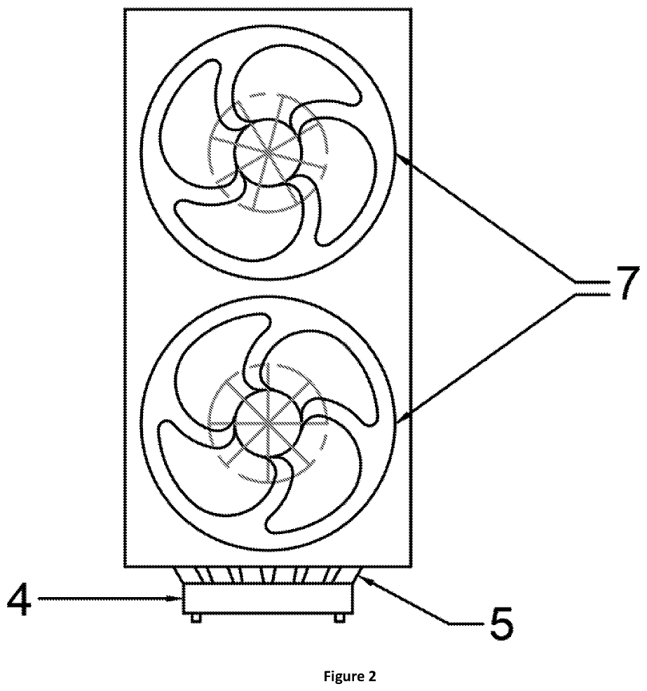

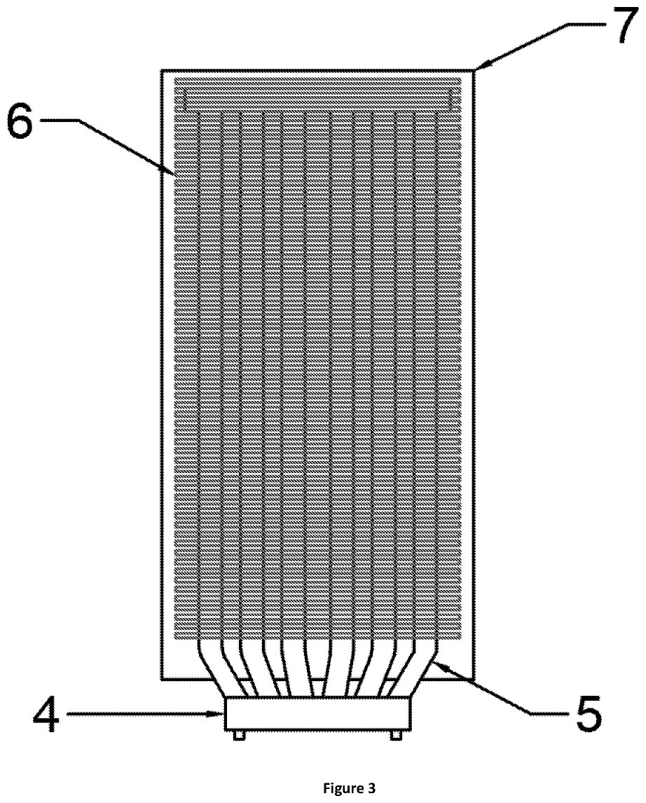

FIG. 1-3 shows the electronic equipment cooling system (1) with heat transfer fluid, which is the subject of the invention, and its details. The invention basically consists of electronic equipment (2), heated component (3) of electronic equipment, plate (4), heat transfer pipes (5), fins (6) and fans (7).

As the current passes through the working electronic equipment (2), the heated component (3) of the electronic equipment heats up over time. In the invention, there are solid particles between 10-200 nanometers, such as colemanite, borax, Al₂O₃, SiO₃, CuO, TiO₂, SiL, boron carbide, szaybelite, boron, in the heat transfer fluid that can change phase, and evaporation accelerates with the help of the heat taken from the heated component (3) of the electronic equipment with the help of the plate (4) thanks to these particles. The heat transfer fluid, which can change phase, transmits the heat very quickly to the fins (6) via the heat transfer pipes (5). The heat accumulated in the fins (6) is removed from the system by means of the fans (7). During the condensation with the fans (7), these solid particles do not clump together (cluster) and do not stick to each other. During condensation, the heat transfer pipes (5) cool down slowly thanks to the nano-sized solid particles that crash into their inner walls. In this way, it has a high capacity to retain heat. Thanks to these nanoparticles, heat pipes can be prepared without vacuuming. There is no need for sintering, corrugation or pocketing on the inner surfaces of the heat pipes. Thus, it can work vertically and horizontally without any shape restrictions.

As an alternative in our invention, the phase changeable heat transfer fluid may contain the above-mentioned solid particles between 10-50 or 50-100 or 100-150 nanometers.

The scope of protection of this application has been determined in the claims section and cannot be limited to what is described above for exemplary purposes, it is clear that a person skilled in the art can demonstrate the innovation in the invention by using similar embodiments and/or can apply this embodiment to other areas with similar purposes used in the relevant technique. Therefore, it is obvious that such structuring will lack the criteria of innovation and especially overcoming the known state of the technique.

### SUMMARY

### Electronic Equipment Cooling System with Heat Transfer Fluid

The invention relates to the electronic equipment cooling system (1) with heat transfer fluid, which quickly removes the unwanted heat from the heated parts of the electronic equipment by transferring it to the phase changeable heat transfer fluid in order to cool the electronic card and all electronic equipment. The invention especially relates to the electronic equipment cooling system, which receives the heat energy from the heated component of the electronic equipment with the help of the plate and transmits this heat energy to the fins, condensing here with the help of the fans, allowing the electronic board to cool, and containing a phase changeable heat transfer fluid containing 10-200 nanometers colemanite, borax, Al₂O₃, SiO₃, CuO, TiO₂, SiL, boron carbide, szaybelite, boron solid particles.

1. The invention relates to the electronic equipment cooling system (1) with heat transfer fluid, which quickly removes the unwanted heat from the heated parts of the electronic equipment in order to cool the electronic card and all electronic equipment, feature; characterized by containing heat transfer fluid a phase changer containing 10-200 nanometer colemanite, borax, Al₂O₃, SiO₃, CuO, TiO₂, SiL, boron carbide, szaybelite, boron solid particles, which receives heat energy from the heated component (3) of the electronic equipment with the help of the plate (4) and transmits this heat energy to the fins (6), allowing the electronic equipment (2) to cool by condensing here with the help of fans (7).

2. It is the cooling system in accordance with claim 1 and its feature is; It is characterized by the fact that it contains a phase changeable heat transfer fluid with a heat transfer coefficient of 16098 W/mK.
